(19) United States
(12) Patent Application Publication
(10) Pub. No.: US 2010/0143207 A1
(43) Pub. Date: Jun. 10, 2010

(54) SEMI-CONDUCTIVE COATINGS FOR A POLYOLEFIN REACTION SYSTEM

(75) Inventors: Michael E. Muhle, Kingwood, TX (US); F. David Hussein, Cross Lanes, WV (US)

Correspondence Address: UNIVATION TECHNOLOGIES, LLC, 5555 SAN FELIPE, SUITE 1950, HOUSTON, TX, 77056, US

(73) Assignee: UNIVATION TECHNOLOGIES, LLC, Houston, TX (US)

(21) Appl. No.: 12/517,514

(22) PCT Filed: Dec. 3, 2007
(86) PCT No.: PCT/US07/24922

§ 371 Date: Jan. 20, 2010

Related U.S. Application Data
(60) Provisional application No. 60/872,708, filed on Dec. 4, 2006.

(51) Int. Cl. B01J 19/00; C23C 16/52

(52) U.S. Cl. 422/139; 427/8

(57) ABSTRACT

A method for selecting a semi-conductive coating to be applied to at least a portion of an inner surface of a polyolefin reaction system wherein the coating has certain electrical properties and a fluidized bed reactor vessel wherein at least a portion of a reactor internal surface is coated with a semi-conductive coating is provided.

### CROSS REFERENCE TO RELATED APPLICATIONS

This application claims the benefit of Ser. No. 60/872,708, filed Dec. 4, 2006, the disclosure of which is incorporated by reference.

### FIELD OF THE INVENTION

The invention relates to a method for selecting a semi-conductive coating to be applied to an inner surface of a polyolefin reaction system wherein the coating has certain electrical properties. In particular, the invention relates to a method for selecting a semi-conductive coating based on the electrical charge performance characteristics of the semi-conductive coating.

### BACKGROUND OF THE INVENTION

In the process for production of polymers, monomers, hydrogen, co-monomer and other raw materials are converted to a solid polyolefin product. For example, polyethylene polymers are generally produced from ethylene monomers, hydrogen, co-monomer and other raw materials. Various processes, including gas phase reaction systems, are used to produce various types of polymers, including gas phase polyethylene reaction systems.

The internal surfaces of a reaction system, particularly a gas phase reaction system, may be composed of carbon steel, and in a normal state appear as a plain, uncoated metal. However, reaction systems that have been in service for a length of time typically have a thin coating of polymer adhered to the interior. The polymer coating in a gas phase process is usually thin and relatively clear, making its presence difficult to detect visually. A gas phase process typically may have a polymer coating of at least about 10 mils thick. In a fluidized bed gas phase process, this coating has a significant effect on the operability of the reactor through its affect on the static charging characteristics of the fluidized bed. In particular, the polymer coating has a significant effect on the operability of metallocene catalyst systems.

Metallocene catalysts allow the production of polyolefins with unique properties such as narrow molecular weight and comonomer composition distribution, thereby improving structural performance in products made with the polymers. While metallocene catalysts yield polymers with unique characteristics, they present new challenges relative to traditional polymerization systems, in particular, the effect on the reactor wall coating.

Sheeting refers to the adherence of fused catalyst and resin particles to the walls and the dome of a reactor. As sheets grow, they eventually dislodge from the wall and, in some instances, disrupt or block fluidization in the reactor. In the event that reactor or dome sheeting compromises the integrity of a reactor, the reactor is shut down and the accumulated sheets are removed. Reactor treatments and retreatments condition the walls of a gas phase reactor with a thin polymer layer which helps to prevent sheeting incidents. Two commonly used techniques for treatment or retreatment of reaction systems involve preparation of the wall (for existing reaction systems this required removal of the bad or contaminated polymer coating) and the in situ creation of a new polymer layer.

The first of these treatment techniques is a chromocene treatment (see, for example, U.S. Pat. Nos. 4,532,311, 4,792,592, and 4,876,320 all of which are incorporated herein by reference). With this method, the walls of the reactor vessel are cleaned, such as by sandblasting. For existing reactors, the sandblasting removes any polymer, including contaminated polymer, from the reactor walls. The reactor is then sealed and purged with nitrogen. A liquid catalyst (e.g. chromocene) and ethylene are then added to the reactor. The liquid catalyst deposits on the reactor wall and reacts with ethylene to form a new polymer coating. After the new polymer coating is formed, the initial product must be monitored closely for the possibility of various quality issues that may arise during initial production due to the presence of sand or concentrated liquid catalyst particles that may remain in the reaction system after treatment.

A second treatment, a retreatment technique, involves hydroblasting the walls of the reactor. In this process, the contaminated polymeric layer is removed with a high-pressure water jet (e.g. hydroblast). The reactor is dried, purged with nitrogen and restarted. The latter restart step employs a relatively high concentration of hydrogen so as to produce a high melt index material (i.e., MI≧2-3) that readily deposits on the reactor wall to form a new polymer coating.

A correlation exists between reactor sheeting and the presence of excess static charges, either positive or negative, in the reactor during polymerization (see, for example, U.S. Pat. Nos. 4,803,251 and 5,391,657). This is evidenced by sudden changes in static levels followed closely by deviation in temperature at the reactor wall. These temperature deviations are either high or low. Low temperatures indicate particle adhesion to the reactor causing an insulating effect from the bed temperature. High deviations indicate reactions taking place in zones of limited heat transfer. When the static charge levels on the catalyst and resin particles exceed critical levels, the particles are driven by electrostatic forces to the grounded metal walls of the reactor. The long residence time of these particles on the reactor wall facilitates melting due to elevated temperatures and particle fusion. Following this, disruption in fluidization patterns is generally evident, such as, for example, catalyst feed interruption, plugging of the product discharge system, and the occurrence of fused agglomerates (sheets) in the product.

In commercial reactors, sheets can vary widely in size, and are usually about 0.5 to 2.0 cm thick and about 2.0 cm to 2.0 meters long, sometimes even longer. Widths of more than 50 cm can occur and can cause the formation of a large reactive agglomerate or “chunk” fusing the reactor contents. The sheets typically have a core composed of fused or melted polymer that is oriented in the long direction of the sheets, and their surfaces are covered with granular resin that is fused to the core. The edges of the sheets can have a hairy or stringy appearance resulting from strands of fused polymer.

Mechanisms to control “sheeting” in fluidized bed reactors are continuing areas of investigation in the industry (see, for example, U.S. Pat. Nos. 5,436,304 and 5,405,922). Various methods described involve monitoring static charges near the reactor wall in regions that display a high propensity of sheeting. For example, static levels are controlled within a predetermined range by introducing a static control agent into the reactor (see U.S. Pat. Nos. 4,803,251 and 5,391,657, which are incorporated herein by reference). In these cases, static charge is measured using static voltage indicators such as voltage probes or electrodes, and measurements are taken at or near the reactor wall, at or below a site commonly plagued by sheet formation and near the distributor plate (see also, U.S. Pat. No. 4,855,370). It is also possible to use amperage indicators such as amperage or current probes or electrodes (see, for example, U.S. Pat. Nos. 5,648,581 and 6,008,662).

In one mechanism of charging, the static charge buildup on individual polymer particles results from frictional contact with the reactor wall through a process known as the triboelectric effect. This charging mechanism depends on, at least, two factors, (i) the nature of the two materials involved, and (ii) the degree of contact. The basic driving force for the transfer of charge to one of the materials is the difference in electrical characteristics of the two materials involved. For example, if no difference exists (i.e., the two materials are identical, such as carbon steel on carbon steel, or polyethylene on polyethylene), little or no charge transfer occurs. Qualitatively, larger amounts of charge are transferred when the two materials are most different in their electrical characteristics (i.e. when they are far apart on the “triboelectric series”) (see, for example, Oguchi and Tamantani, “Contact Electrification in Inorganic Binary Compounds” J. Electrochem. Soc., Solid State Science and Technology, April 1986, pp. 841-847; and U.S. Pat. No. 5,391,657). Typical charge flows (currents) are of magnitude 0.1 to 10 microamperes per square meter of reactor surface area. Although these currents are low, relatively high levels of electrical charge accumulate over time in a polyolefin reactor. This accumulation is enabled by the highly insulating characteristics of polymer and catalyst particles. The frictional electrification of the polymer and catalyst particles can be strongly influenced by the type of polymer that is being produced. In particular, the polymer molecular weight has a strong effect, with higher molecular weight polymers being more prone to developing high levels of static charge.

Static charging in the fluid bed is also strongly influenced by the presence of minute quantities of charge-inducing impurities. It is theorized that reaction of impurities with the catalyst, co-catalyst, or activator may also impart an electrical charge to individual particles. The accumulation of electrical charges on the polymers particles can result in high levels of static charge in the fluid bed if the charge is not properly dissipated. One path for dissipation of static induced by impurities is by contact with the reactor wall and transfer of the charge to the reactor wall. The degree of contact is dependent on the impact velocity of the particles both amongst themselves and against the wall and recycle system components such as the heat exchanger, compressor and distributor plate. The distributor plate caps are particularly prone to high generation of electrical charges.

Water add-back is one technique used as an attempt to counteract static accumulation in the fluid bed (see, for example, U.S. Pat. No. 4,855,370). However, as the condition of the polymer wall coating on the reactor walls deteriorates, increasingly larger amounts of water are required to control the static. Eventually, the reaction system becomes too unstable and sheeting events can lead to a reactor shutdown. In such instances, a retreatment of the reactor is required to reestablish stable operation. Retreatments can require about 5-10 days or more to complete, translating into substantial lost production time.

Other background references include U.S. Pat. Nos. 6,586,538, 6,335,402, 6,252,015, 5,856,019, 5,541,269, 5,457,170, 4,956,427, 4,381,384, 4,344,993, 4,262,109, 3,995,097, 3,738,974, 3,520,859, 3,507,849; WO 2004/029098; Japanese Publ. Nos. 60-115602, 2006-046608, 2004-189960; Chubb, J. N., “Instrumentation and standards for testing static control materials” IEEE Trans. Ind. Appl. 26(6), November/December 1990, p 1182; Chubb, J. N., “Dependence of charge decay characteristics on charging parameters” Proceedings of Electrostatics 1995 Conference, Univ. of York, Apr. 3-5, 1995 Inst. Phys. Confr. Series, 143, p 103; Chubb, J. N., “The assessment of materials by tribo and corona charging and charge decay measurements” Proc. Inst. Phys. Confr. Electrostatics 1999, Univ. Cambridge, March 1999a, Inst. Phys. Confr. Series, 163, p 329; Chubb, J. N., “Measurement of tribo and corona charging features of materials for assessment of risks from static electricity” Trans IEEE Ind Appl., 36(6), November/December 2000, p 1515; and Chubb, J. N., “Experience with electrostatic fieldmeter instruments with no earthing of the rotating chopper” Inst. Phys. Confr. Electrostatics 1999, Univ. Cambridge, March 1999b, Inst. Phys. Confr. Series, 163, p 443; and Chubb, J. N. “New approaches for electrostatic testing of materials” Journal of Electrostatics 2002-2003 Elsevier Science Publishers B.V. Amsterdam, NL vol. 54, no. 3-4, March 2002 pages 0304-3886 (XP004341138).

Due to the downtime and limitations presented by current methods of providing a reactor coating for polyolefin reaction systems, a cost effective and efficient method of selecting a coating for the inner surface of the reaction system, particularly the reactor vessel, is needed. In particular, a method of selecting a coating is needed to avoid at least one of the concerns of extended downtime, handling of the liquid catalyst, reaction of the catalyst on the walls of the reactor and minimizing product contamination issues.

### SUMMARY OF THE INVENTION

In one embodiment, the invention provides a method for selecting a semi-conductive coating for a polyolefin reaction system comprising the steps of: 1) determining a charge decay performance of a semi-conductive coating; 2) selecting the semi-conductive coating based on the charge decay performance of the semi-conductive coating; and 3) applying the semi-conductive coating to at least a portion of an inner surface of a polyolefin reaction system.

In a class of embodiments, the semi-conductive coating is selected by comparing a desired charge decay performance to the charge decay performance of the semi-conductive coating. In another class of embodiments, the desired charge decay performance is compared to the charge decay performance of a plurality of semi-conductive coatings and the semi-conductive coating which has the closest charge decay performance to the desired charge decay performance is selected.

In yet another class of embodiments, the charge decay performance is determined by applying a corona voltage to the semi-conductive coating and measuring voltage retention over time of the semi-conductive coating. The corona voltage applied is, for example, between minus 10,000 and positive 10,000 volts, although in some embodiments higher levels can also be utilized.

In other embodiments, the charge decay performance of the semi-conductive coating is characterized as having a normalized residual charge of greater than about 100 volts; greater than about 200 volts; greater than about 400 volts; about 100 to about 5,000 volts; about 200 to about 2,500 volts; or about 400 to about 2,000 volts. In other embodiments, the charge decay performance of the semi-conductive coating is characterized as having a rate of charge decay of greater than about 10% in 300 seconds; greater than about 25% in 300 seconds; greater than about 50% in 300 seconds; or greater than about 90% in 300 seconds.

In any of the embodiments described herein, the semi-conductive coating may be a solvent-based polymeric coating.

In any of the embodiments described herein, the semi-conductive coating may be a manually applied coating.

In any of the embodiments described herein, the polyolefin reaction system may be a polyethylene reaction system.

In another class of embodiments, the method may also include the step of confirming the electric performance of the semi-conductive coating by: 1) placing a tube internally coated with the semi-conductive coating in a Faraday cage; 2) charging polymer to the tube; 3) fluidizing the polymer; and 4) measuring the net charge generation as a function of time.

In other embodiments, the method comprises the steps of: 1) determining an electrical charge performance characteristic of a semi-conductive coating; 2) selecting the semi-conductive coating based on the electrical charge performance characteristic; and 3) applying the semi-conductive coating to at least a portion of an inner surface of a polyolefin reaction system.

In one embodiment, a portion of an applied electrical charge imposed on a semi-conductive coating surface is retained by the semi-conductive coating for at least about 300 seconds. In other embodiments, the retained portion of the applied electrical charge is greater than about 1% of the applied electrical charge; greater than about 2% of the applied electrical charge; greater than about 4% of the applied electrical charge; about 1% to 90% of the applied electrical charge; about 1% to 50% of the applied electrical charge; about 2% to 25% of the applied electrical charge; or about 4% to 20% of the applied electrical charge.

In yet another embodiment, the electrical charge performance characteristic represents the ability of the semi-conductive coating to transfer an applied electrical charge imposed on a semi-conductive coating surface to a substrate. In other embodiments, the semi-conductive coating transfers greater than about 10% of the applied electrical charge to the substrate within about 300 seconds; the semi-conductive coating transfers greater than about 25% of the applied electrical charge to the substrate within about 300 seconds; the semi-conductive coating transfers greater than about 50% of the applied electrical charge to the substrate within about 300 seconds; semi-conductive coating transfers greater than about 90% of the applied electrical charge to the substrate within about 300 seconds.

Another class of embodiments provides a fluidized bed reactor vessel wherein at least a portion of a reactor internal surface is coated with a semi-conductive coating, wherein the semi-conductive coating comprises a polyphenylene sulfide (PPS) and polytetrafluoroethylene mixture, mineral fillers, a graphite in a polymeric base, or carbon nanotube fibers in a polymeric base, and wherein the semi-conductive coating is characterized as having a rate of charge decay of greater than about 10% in 300 seconds.

In some embodiments, the semi-conductive coating on the reactor internal surface is epoxy-based, while in others is solvent-based.

One class of embodiments provides a fluidized bed reactor vessel wherein at least a portion of a reactor internal surface is coated with a semi-conductive coating, wherein the semi-conductive coating comprises a polyphenylene sulfide and Polytetrafluoroethylene mixture, and wherein the semi-conductive coating is characterized as having a rate of charge decay of greater than about 10% in 300 seconds.

Another class of embodiments provides a fluidized bed reactor vessel wherein at least a portion of a reactor internal surface is coated with a semi-conductive coating, wherein the semi-conductive coating comprises mineral fillers, and wherein the semi-conductive coating is characterized as having a rate of charge decay of greater than about 10% in 300 seconds. In some embodiments, the mineral fillers comprise elements or oxides of silicon, aluminum, boron, or magnesium.

Yet another class of embodiments provides a fluidized bed reactor vessel wherein at least a portion of a reactor internal surface is coated with a semi-conductive coating, wherein the semi-conductive coating comprises a graphite in a polymeric base, and wherein the semi-conductive coating is characterized as having a rate of charge decay of greater than about 10% in 300 seconds.

Yet another class of embodiments provides a fluidized bed reactor vessel wherein at least a portion of a reactor internal surface is coated with a semi-conductive coating, wherein the semi-conductive coating comprises carbon nanotube fibers in a polymeric base, and wherein the semi-conductive coating is characterized as having a rate of charge decay of greater than about 10% in 300 seconds.

In any of the classes of embodiments that provide a fluidized bed reactor vessel wherein at least a portion of a reactor internal surface is coated with a semi-conductive coating, the rate of charge decay of the semi-conductive coating may be greater than about 25% in 300 seconds, greater than about 50% in 300 seconds, greater than about 90% in 300 seconds, or between about 10% and about 90% in 300 seconds.

Another class of embodiments provides a fluidized bed reactor vessel wherein at least a portion of a reactor internal surface is coated with a semi-conductive coating, wherein the semi-conductive coating comprises a polyphenylene sulfide and polytetrafluoroethylene mixture, mineral fillers, a graphite in a polymeric base, or carbon nanotube fibers in a polymeric base, and wherein the semi-conductive coating is characterized as having a normalized residual charge with an absolute value of about 100 to about 5,000 volts about 300 seconds after applying a corona voltage with an absolute value of about 8,000 to about 12,000 volts.

In some embodiments, the normalized residual charge of the semi-conductive coating on the reactor internal surface has an absolute value of about 200 to about 2,500 volts, or about 400 to about 2,000 volts.

Other features and advantages of the present invention will become apparent from the following detailed description. It should be understood, however, that the detailed description and the specific examples, while indicating preferred embodiments of the invention, are given by way of illustration only, since various changes and modifications within the spirit and scope of the invention will become apparent to those skilled in the art from this detailed description.

### BRIEF SUMMARY OF THE DRAWINGS

FIG. 1 is a graph of the charge decay performance of various coatings including a commercial reactor coating after exposing test samples to a corona voltage of 10,000 volts.

FIG. 2 is a graph of the charge decay performance of various coatings, including a graphite-containing coating, after exposing test samples to a corona voltage of 10,000 volts.

FIG. 3 is a graph of the charge decay performance of various coatings, including a carbon nanotube-containing coating, after exposing test samples to a corona voltage of 10,000 volts.

FIG. 4 is a graph of the charge decay performance of a graphite-containing coating and a carbon nanotube-containing coating after exposing test samples to a corona voltage of 10,000 volts. The voltage and time scale has been expanded in this figure relative to FIG. 3.

FIG. 5 is a graph of the charge decay performance of a composite coating containing silica that was applied to a pilot plant reactor before the reactor had been placed in operation and after the reactor had been in operation for 31 days.

FIG. 6 is a schematic drawing of a gas-phase fluidized bed reaction system.

### DETAILED DESCRIPTION OF THE INVENTION

The current invention provides a method for selecting a semi-conductive coating to be applied to at least a portion of an inner surface of a polyolefin reaction system wherein the coating has specific electrical properties. One embodiment of the invention provides a method of selecting a semi-conductive coating for a polyolefin reaction system comprising the steps of: 1) determining a charge decay performance of a semi-conductive coating; 2) selecting the semi-conductive coating based on the charge decay performance; and 3) applying the semi-conductive coating to at least a portion of an inner surface of a polyolefin reaction system.

In gas phase polymerization reaction systems, frictional contact of polymer particles with the walls of the reaction vessel may impart an electrical charge to the polymer particles. Frictional contact of dissimilar materials can create an electrical charge in one of the materials (triboelectrification). Accordingly, without being bound to theory, it is believed that a coating similar in composition to the polymer in the fluid bed may reduce, decrease, or prevent the accumulation of electrical charges in the polymer particles. Reaction vessels with a “good quality polymer coating” exhibit a reduced tendency to accumulate an electrical charge in the polymer particles. Reducing the charge accumulation in the polymer particles reduces the potential to form sheets. A stable reaction system in good condition operates for extended periods of time (months or years) without excessive static accumulation and without operational problems due to sheeting. A reaction system in this state is said to have a good static baseline and is relatively insensitive to the properties of the resin product. The term “good quality polymer coating” as used herein refers to a polymer coating formed on the inner surface and a polyolefin reactor wall that results in stable reaction system operations. In one embodiment, a “good quality polymer coating” is thin, for example, at least about 10 mils, substantially lacks oxygen contamination such as that present as metal oxide, and is effective at maintaining normal static charge levels in the polymer particles during polymerization.

A “good quality polymer coating” can be formed “naturally” over time through normal operation of the reaction system on certain polymer types. Without being bound to theory, it is believed that this “natural” coating occurs due to the physical deposition of low molecular weight components from the polymer grades being produced and is more pronounced with lower molecular weight polymer grades. The “natural” formation may require periods of operation on polymer grades that may not be desirable to market or may result in undesirable sheeting incidents. In the chromocene treatment method discussed above, a “good quality polymer coating” is created in situ by depositing a catalyst on the reactor walls and reacting the catalyst with monomer. Without being bound to theory, it is believed that a “good quality polymer coating” on the reactor wall prevents charges from being created and also allows accumulated charges to dissipate.

In one class of embodiments, the invention provides for a method of selecting a semi-conductive coating that will perform in a similar fashion to a good quality polymer coating. The term “semi-conductive coating,” as used herein, refers to any coating applied on a surface that allows at least a portion of an electrical charge imposed on the surface of the coating to pass to the surface below the coating (referred to herein as the substrate). The semi-conductive coating can be any coating that is compatible with the polyolefin process of interest. In one embodiment, the semi-conductive coating is a solvent-based polymer coating. In another embodiment, the semi-conductive coating is an epoxy-based polymer coating. A polymer coating can be any coating containing a polyolefin polymer. Preferred polymer coatings include a polyphenylene sulfide (PPS), a PPS and polytetrafluoroethylene mixture, an epoxy containing mineral fillers, a graphite in a polymeric base, or carbon nanotube fibers in a polymeric base. The coating may also be a mixture of ultra high MW and medium MW polyethylene. Mineral fillers include those containing the elements: silicon, aluminum, boron, and magnesium. Oxides of these elements are preferred but one is not limited to these compositions. In one embodiment, the semi-conductive coating is durable and peel resistant. In another embodiment, the semi-conductive coating has variable electrical properties that can be adjusted as desired.

The term “charge decay performance” as used herein refers a combination of the rate that a coating dissipates a corona charge imposed on the surface of the coating and the level of residual charge present on the surface after a period of time. Corona charge deposition provides a means to simulate practical charging events under controlled and predetermined conditions of initial surface voltage and charge polarity. Corona discharges occur in gaseous media when the localized electric field in the neighborhood of a body exceeds the electrical breakdown voltage of the gaseous medium. They are usually generated as a brief pulse of high voltage to a receiving surface. This process is referred to as corona charge deposition. The charge transfer results in a high initial voltage on the receiving surface, which is a semi-conductive coating in the present case. The voltage level decays over time and is referred to as a charge decay curve. The charge decay curve generally exhibits a plateau voltage after an initial and rapid fall of surface voltage. A residual charge is the plateau voltage measured at a given period of time after the corona charge is imposed on the surface. The charge decay performance of a surface can be measured by any suitable commercially available device, for example, a JCI 155 Charge Decay Meter (JCI, Cheltenham, UK). Because polarity can vary, unless stated otherwise, all voltage readings referenced herein are the absolute values of the voltage.

The charge decay performance of a semi-conductive coating can be determined by any suitable method of determining the response of the semi-conductive coating to transferring a voltage to the surface of the semi-conductive coating and measuring the voltage on the surface as a function of time. Because the charge decay performance of a semi-conductive coating can vary with the thickness of the coating, measurements of the charge decay performance should be normalized to a standard thickness for comparison purposes. In one embodiment, the charge decay performance of a semi-conductive coating is determined by applying a corona charge voltage about −12,000 to about +12,000 volts, about ±6,000 to about ±12,000 volts, or about ±8,000 to about ±12,000 volts, to the surface of the semi-conductive coating and measuring the voltage on the surface of the semi-conductive coating as a function of time. The voltage measurements can be normalized to a standard thickness for comparison purposes. In one embodiment, the charge decay performance is determined by preparing a sample metal coupon coated with the semi-conductive coating, applying a corona charge voltage of about 8,000 to 12,000 volts to the coated sample, and measuring the voltage response over time. In another embodiment, the charge decay performance can be characterized by the manufacturer of the coating, testing laboratories, or by other users of the semi-conductive coating and supplied to the current user of the method.

In one embodiment of the invention, the semi-conductive coating is selected based on the charge decay performance of the semi-conductive coating. The selection may be based on comparisons of graphs, by mathematical models, by specified performance criteria, or other suitable method. In one embodiment, the charge decay characteristics of a “good quality polymer coating” are measured to obtain a desired charge decay performance. The semi-conductive coating exhibiting a charge decay performance similar to the desired charge decay performance is selected. In another embodiment, the desired charge decay performance is compared to the charge decay performance of a plurality of semi-conductive coatings and the semi-conductive coating which has the closest charge decay performance to the desired charge decay performance is selected.

In another embodiment, the charge decay performance of the semi-conductive coating is characterized as having a normalized residual charge of greater than about 100 volts. As used herein, a “normalized residual charge” is the absolute value of voltage on the surface of the semi-conductive coating after a corona voltage applied to the surface has partially dissipated, the voltage readings being normalized to 10 mil coating thickness. The voltage reading is typically taken a period of time after the corona voltage is applied, for example 300 seconds, that is a sufficient time for the voltage to stabilize to a degree (reach a noticeable plateau). The residual charge reading may be taken with any suitable instrument, for example a JCI Charge Decay Meter. The corona discharge voltage may vary depending on the test instrument. In one class of embodiments, the corona voltage applied is between about −10,000 and about +10,000 volts. In another class of embodiments, the residual charge reading is taken 300 seconds after the corona voltage is applied. The voltage readings can be normalized to a 10 mil thickness using the following equation:

Normalized Charge=Actual Charge×(10/T)ⁿ
where:
T=actual thickness of the coating in mils; and
n is typically between 0.5 and 1.5, and n may be equal to 0.749.

In one embodiment, the normalized residual charge is measured by 1) preparing a test sample coated with the semi-conductive coating; 2) measuring a thickness of the semi-conductive coating on the test sample; 3) exposing the test sample to a fixed corona discharge of a predetermined polarity and a predetermined magnitude; 4) measuring a voltage on the semi-conductive coating for a time sufficient to observe a plateau of the voltage or until the voltage approaches zero to produce a data set; 4) determining a normalization constant of the test sample; and 5) converting the measured plateau voltages to a normalized residual charge value. In one embodiment, said normalization constant is derived from plotting a logarithm transformed data set against a logarithm-transformed thickness.

In any embodiment herein, the charge decay performance of the semi-conductive coating may be characterized as having a normalized residual charge of greater than about 200 volts, greater than about 400 volts, or greater than about 600 volts. In another embodiment, the charge decay performance is characterized as having a normalized residual charge of about 100 to about 5,000 volts, about 200 to about 2,500 volts, or about 400 to about 2,000 volts.

In any other embodiment herein, the charge decay performance of the semi-conductive coating may be characterized as having a rate of charge decay of greater than about 10% in 300 seconds. As used herein, the “rate of charge decay” refers to the rate of decrease of charge voltage on the surface of the semi-conductive coating after a corona charge is imposed on the surface. In other embodiments, the rate of charge decay may be greater than about 25% in 300 seconds, greater than about 50% in 300 seconds, or greater than about 90% in 300 seconds.

In another embodiment, the method comprises the steps of: 1) determining an electrical charge performance characteristic of a semi-conductive coating; 2) selecting the semi-conductive coating based on the electrical charge performance characteristic; and 3) applying the semi-conductive coating to at least a portion of an inner surface of a polyolefin reaction system. As used herein, “electrical charge performance characteristic” refers to any parameter selected that characterizes how a semi-conductive coating, creates, accepts, transfers, conducts, or dissipates electrical charges. In one embodiment, the electrical performance characteristic represents the ability of the semi-conductive coating to transfer an electrical charge imposed on the semi-conductive coating surface to a substrate. As used herein, substrate means the surface, for example, metal, that is coated by the semi-conductive coating.

In another embodiment of the invention, the electrical charge performance characteristic of the semi-conductive coating is characterized as having an applied electrical charge imposed on a semi-conductive coating surface, wherein a portion of the applied electrical charge is retained by the semi-conductive coating for at least about 300 seconds. In one embodiment, the retained portion of the applied electrical charge is greater than about 1% of the applied electrical charge, the retained portion of the applied electrical charge is greater than about 2% of the applied electrical charge, or the retained portion of the applied electrical charge is greater than about 4% of the applied electrical charge. In another embodiment, the retained portion of the applied electrical charge is about 1% to 90% of the applied electrical charge, about 1% to 50% of the applied electrical charge, about 2% to 25% of the applied electrical charge, or about 4% to 20% of the applied electrical charge.

In yet another embodiment, the electrical charge performance characteristic represents the ability of the semi-conductive coating to transfer an applied electrical charge imposed on the semi-conductive coating surface to a substrate. In one embodiment, the semi-conductive coating transfers greater than about 10% of the applied electrical charge to the semi-conductive coating surface to the substrate within about 300 seconds. In other embodiments, the semi-conductive coating transfers greater than about 25% of the applied electrical charge within about 300 seconds, greater than about 50% of the applied electrical charge to the substrate within about 300 seconds, or greater than about 90% of the applied electrical charge to the substrate within about 300 seconds.

The performance of a semi-conductive coating in a polyolefin reaction system, particularly a gas-phase reaction system, may be confirmed with further testing. In one embodiment of the invention, the electric performance of the semi-conductive coating is confirmed by 1) placing a tube internally coated with the semi-conductive coating in a Faraday cage; 2) charging polymer to the tube; 3) fluidizing the polymer; and 4) measuring the net charge generation as a function of time. Such methodology and the handling of such equipment is well within the skill in the art.

In a class of embodiments, the method is suitable for selecting a semi-conductive coating to be applied on any surface of a polyolefin reaction system. In an embodiment of the invention, the semi-conductive coating is applied to at least a portion of an inner surface of a polyolefin reaction system, such as a gas phase reaction system. In one embodiment, the semi-conductive coating is applied to at least a portion of the inner walls of a reactor vessel in a gas phase reaction system.

The semi-conductive coating is applied by any method known to one of skill in the art that is appropriate for the selected coating. In one embodiment of the invention, the semi-conductive coating is applied by forming the coating in situ by reacting a catalyst with a monomer. Preferred methods of in situ application of a semi-conductive coating include those described in U.S. Pat. Nos. 4,532,311, 4,792,592, and 4,876,320. In another embodiment, the semi-conductive coating is a manually applied coating. As used herein, manually applied means applied by painting, spraying, or other coating application techniques, as opposed to an in situ formation, or formation by natural operations. Manually applied coatings are typically applied and dried or cured before being placed in service. In one embodiment, a polymeric based coating is applied using a manual process wherein the coating is dissolved in an appropriate solvent or melted and then applied to the surface of the reaction system and cured in place. Details of how to apply a commercially available semi-conductive coating are typically available from the supplier of coating. In one embodiment, the semi-conductive coating can be applied to any desired thickness.

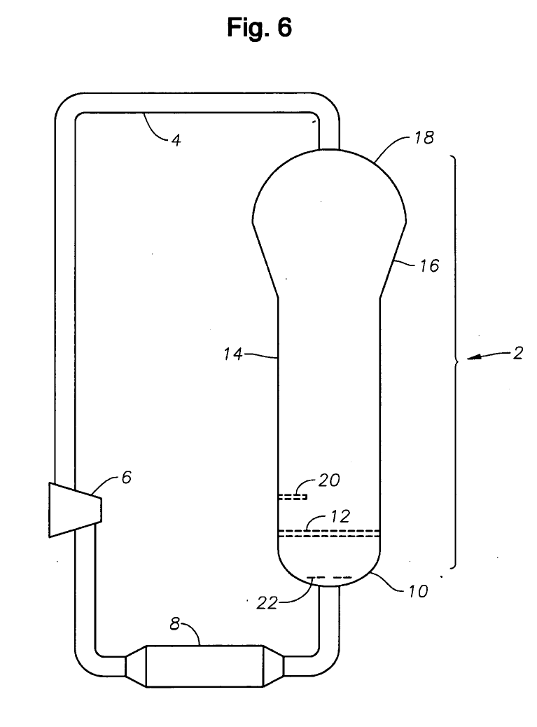

In any embodiment herein, a fluidized bed reactor may be provided wherein at least a portion of a reactor internal surface is coated with a semi-conductive coating. As used herein, a “fluidized bed reactor” refers to the reactor vessel in a fluidized bed polymerization system. The fluidized bed polymerization system can be any gas-phase fluidized bed polymerization process, for example a polyethylene, polypropylene, or ethylene-propylene rubber gas-phase polymerization system. Referring to FIG. 6, a fluidized bed polymerization system may comprise a reactor vessel 2, a recycle line 4, a circulating compressor 6, and a cooler 8. The reactor vessel 2, may comprise a bottom head 10, a gas-distributor plate 12, a straight section (also referred to as a bed section) 14, an expanded section 16, and a dome 18. As used herein, “a reactor internal surface” refers to any surface inside of the reactor vessel. In at least one embodiment, the reactor internal surface may be: the inside of the bottom head 10, straight section 14, expanded section 16, or dome 18; or the top or bottom of the gas-distributor plate 12. In some embodiments, the reactor internal surface may refer to support tubes 20, a gas deflector 22, or surfaces of other components inside the reactor vessel. In any embodiment herein, the term “inner surface of a polyolefin reaction system” may include any surface inside of the reactor vessel 2, recycle line 4, circulating compressor 6, or cooler 8 of a fluidized bed polymerization system.

One class of embodiments of the invention provides a fluidized bed reactor vessel wherein at least a portion of a reactor internal surface is coated with a semi-conductive coating that comprises polyphenylene sulfide.

Another class of embodiments of the invention provides a fluidized bed reactor vessel wherein at least a portion of a reactor internal surface is coated with a semi-conductive coating that comprises a polyphenylene sulfide and polytetrafluoroethylene mixture.

Another class of embodiments of the invention provides a fluidized bed reactor vessel wherein at least a portion of a reactor internal surface is coated with a semi-conductive coating that comprises mineral fillers. In some embodiments, the mineral fillers comprise elements of silicon, aluminum, boron, or magnesium. In other embodiments, the mineral fillers comprise oxides of silicon, aluminum, boron, or magnesium. Suitable mineral-filled coatings are available from commercial suppliers. For example, suitable silica-filled coatings are commercially available from commercial suppliers, for example Curran International.

Another class of embodiments of the invention provides a fluidized bed reactor vessel wherein at least a portion of a reactor internal surface is coated with a semi-conductive coating that comprises a graphite in a polymeric base.

Another class of embodiments of the invention provides a fluidized bed reactor vessel wherein at least a portion of a reactor internal surface is coated with a semi-conductive coating that comprises carbon nanotube fibers in a polymeric base.

Another class of embodiments of the invention provides a fluidized bed reactor vessel wherein at least a portion of a reactor internal surface is coated with a semi-conductive coating that comprises polyphenylene sulfide (PPS), a PPS and polytetrafluoroethylene mixture, mineral fillers, a graphite in a polymeric base, or carbon nanotube fibers in a polymeric base.

In at least one embodiment, the semi-conductive coating may be epoxy-based. As used herein, “epoxy-based” refers to a coating that is applied to a surface wherein the coating comprises a catalyzing agent or hardener that reacts with the coating components to cure the coating.

In other embodiments, the semi-conductive coating is solvent-based. As used herein, “solvent-based” refers to a coating that is applied to a surface wherein the coating uses a volatile solvent as the carrier for the non-volatile coating components. The volatile solvent typically does not become part of the semi-conductive coating. Volatile solvents may include water, aliphatics, aromatics, alcohols, and ketones. In some embodiments, the volatile solvent may be an organic solvent such as petroleum distillate, alcohols, ketones, esters, glycol ethers, and the like. In some cases, a volatile low-molecular weight synthetic resins may also serve as a diluent.

In some applications, the fluidized bed reactor vessel may have at least a portion of a reactor internal surface is coated with a semi-conductive coating comprising a mixture of an ultra high molecular weight (UHMW) polyethylene and a medium molecular weight polyethylene. The medium molecular weight polyethylene may be a high density polyethylene. This coating may be generated using a transition metal based catalyst in the presence of ethylene monomer or flame spray applied to the reactor vessel. As used herein, “ultra high molecular weight polyethylene” refers to a polyethylene polymer that has long chains, for example with a carbon chain length of at least 50,000 carbons. The UHMW polyethylene may have an average molecular weight of greater than 1 million Daltons, or may be between about 1 million and 10 million Daltons. As used herein, “medium molecular weight polyethylene” refers to a polyethylene polymer that has an average molecular weight of between about 10 thousand to 1 million Daltons. The medium molecular weight polyethylene may have a broad molecular weight distribution, with an average molecular weight of between about 10 thousand to 1 million Daltons. As used herein, “high density polyethylene” refers to a polyethylene with a density of greater than about 0.940 g/cm² or between about 0.940 to about 0.97 g/cm² as measured according to ASTM 2839.

Another class of embodiments provides a fluidized bed reactor vessel wherein at least a portion of a reactor internal surface is coated with a semi-conductive coating that comprises polyphenylene sulfide (PPS), a PPS and polytetrafluoroethylene mixture, mineral fillers, a graphite in a polymeric base, or carbon nanotube fibers in a polymeric base. In this class of embodiments, the semi-conductive coating may be characterized as having a normalized residual charge with an absolute value of about 100 to about 5,000 volts, about 200 to about 2,500 volts, or about 400 to about 2,000 volts about 300 seconds after applying a corona voltage with an absolute value of about 8,000 to about 12,000 volts.

The method of this invention is also directed toward a polyolefin reaction process of one or more olefin monomers having from 2 to 30 carbon atoms, 2 to 12 carbon atoms, or 2 to 8 carbon atoms. The invention is particularly well suited to the polymerization of two or more olefin monomers of ethylene, propylene, butene-1, pentene-1, 4-methyl-pentene-1, hexene-1, octene-1 and decene-1.

In one embodiment of the invention, a copolymer of ethylene is produced, where with ethylene, a co monomer having at least one alpha-olefin having from 4 to 15 carbon atoms, from 4 to 12 carbon atoms, or from 4 to 8 carbon atoms, is polymerized in a gas phase process.

In one embodiment, the invention is directed to a process, particularly a gas phase process, for polymerizing ethylene alone or with one or more other monomers including butane or hexane or other olefins having from 4 to 12 carbon atoms wherein at least a portion of an inner surface of the reaction vessel has a semi-conductive coating applied which was selected by a method of the invention. Polymers may be produced using metallocene-type catalysts as described in, for example, U.S. Pat. Nos. 5,296,434 and 5,278,264.

The reactor pressure in a gas phase process may vary from about 100 psig (690 kPa) to about 500 psig (3448 kPa), in the range of from about 200 psig (1379 kPa) to about 400 psig (2759 kPa), or in the range of from about 250 psig (1724 kPa) to about 350 psig (2414 kPa).

The reactor temperature in the gas phase process may vary from about 30° C. to about 120° C., about 60° C. to about 115° C., from about 70° C. to 110° C., or from about 70° C. to about 95° C.

Other gas phase processes contemplated by the process of the invention include those described in U.S. Pat. Nos. 5,627,242, 5,665,818 and 5,677,375, and European publications EP-A-0 794 200, EP-A-0 802 202 and EP-B-634 421.

It is to be understood that while the invention has been described in conjunction with the specific embodiments thereof, the foregoing description is intended to illustrate and not limit the scope of the invention. Other aspects, advantages and modifications will be apparent to those skilled in the art to which the invention pertains.

Therefore, the following examples are put forth so as to provide those skilled in the art with a complete disclosure and description of how to make and use the compounds of the invention, and are not intended to limit the scope of that which the inventors regard as their invention.

### EXAMPLES

Measurements were taken of the charge decay performance of a semi-conductive coating present in a commercial reactor created using a chromocene treatment procedure, such as described in U.S. Pat. No. 4,532,311. Test samples of various commercially available semi-conductive coatings were prepared and the charge decay performance of the test samples was measured. Based on the charge decay measurements of the commercially available semi-conductive coatings, a specific coating was selected and tested in a pilot-scale polymer reactor. Reactor operation after coating with the selected semi-conductive coating was stable and free of sheeting, with reduced levels of charging on the plate as measured by static probes attached to the plate caps.

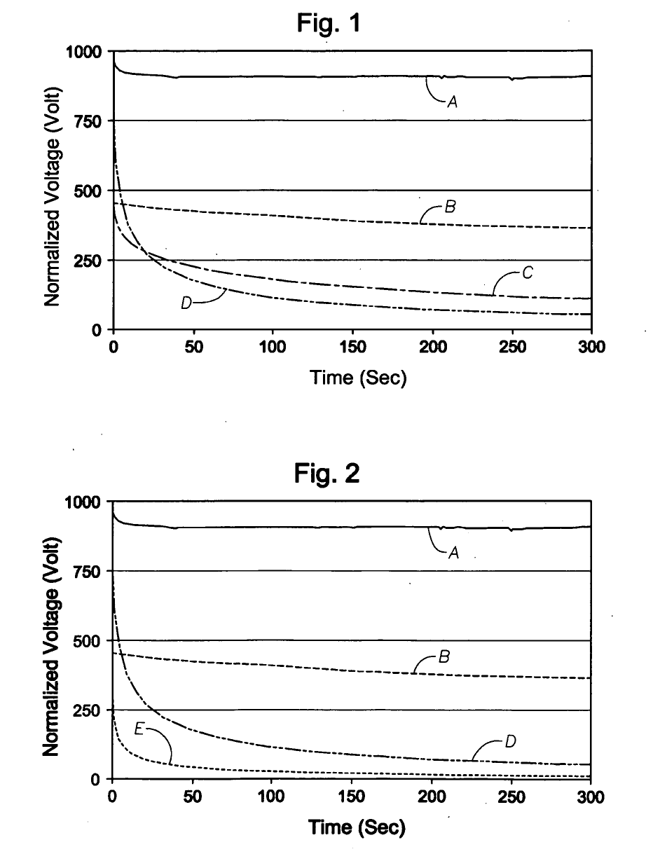

Measurements of the charge decay performance of the chromocene reactor wall coating in the commercial reactor, and the commercially available semi-conductive coatings tested are summarized in the FIGS. 1-5 and discussed below. FIGS. 1-5 are data plots of the normalized voltage readings (Y axis) over time in seconds (X axis). The charge decay voltage measurements in the examples and shown in FIGS. 1-5 were normalized to a 10 mil thickness according to the following equation:

Normalized Charge=Actual Charge×(10/T)ⁿ
where:
T=actual thickness of the coating in mils; and
n=0.749.

### Chromocene Reactor Wall Coating

Measurements of coating thickness and charge decay were taken from a commercial scale reactor with a semi-conductive coating that was applied using a chromocene treatment procedure. A JCI 155 charge decay meter was used to take the charge decay measurements. The reactor was approximately 14.5 feet in diameter with a reaction section height of 44.5 feet from the distributor plate. Measurements were taken on the reactor wall surface at a height of approximately 4 feet from the distributor plate. A corona voltage of 10,000 volts was applied to the reactor wall. The result of the measurement of the reactor wall coating is shown as a plot of the charge decay in FIGS. 1-3, and 5 and labeled as “A.” This serves as a reference point in comparison of alternative coatings.

### Selection of Commercially Available Coating

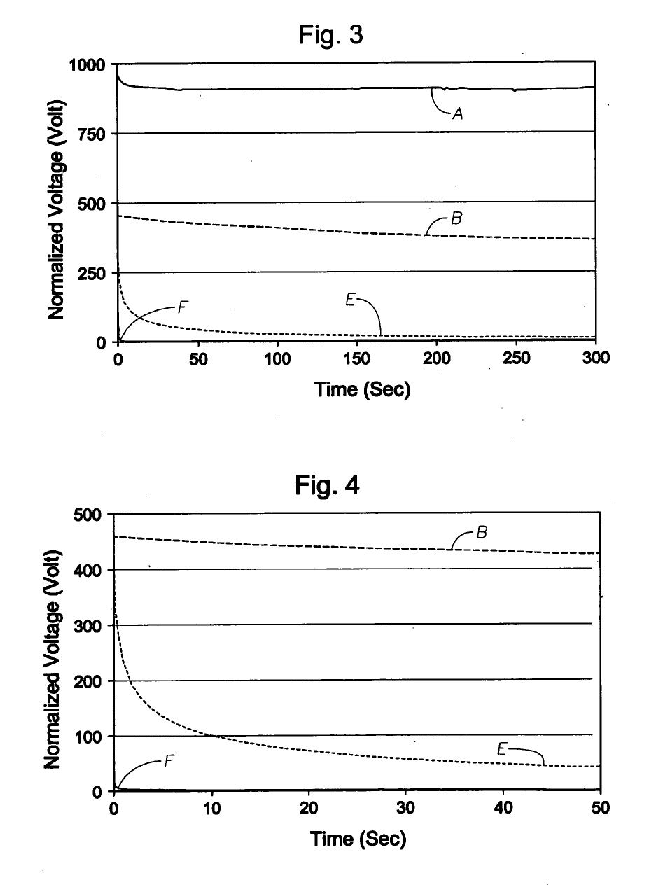

Carbon steel metal foil was obtained from Goodfellow Cambridge Limited that was 0.1 mm thick. Five by eight millimeter coupons were cut from the foil and coated with coating materials shown in Table 1. The coatings were then tested with a JCI charge decay meter using an applied corona voltage of 10,000 volts. Thickness measurements of the coating were also obtained. Results of the charge decay measurements are shown and compared in FIGS. 1-4. The curve labeled “B” in FIGS. 1-3 refers to the charge decay of a coating using a combination of polyphenylene sulfide (PPS) and polytetrafluoroethylene (PTFE or Teflon™). The curve labeled “C” in FIG. 1 refers to the charge decay of a coating using PPS only. The curve labeled “D” in FIGS. 1 and 2 refers to the charge decay of a coating using a composite coating containing silica. The curve labeled “E” in FIGS. 2-4 refers to the charge decay of an epoxy based conductive coating containing graphite fillers. The curve labeled “F” in FIGS. 3-4 refers to the charge decay of an epoxy based conductive coating containing carbon nanotube fiber filling.

TABLE I

| | Drawing |
|---|---|
| Coating | Label |
| Combination of Polyphenlene Sulfide and | “B” |
| Polytetrafluoroethylene | |
| Polyphenlene Sulfide | “C” |
| Silica mineral filled coating | “D” |
| Epoxy based coating containing graphite filler | “E” |
| Epoxy based coating containing carbon | “F” |
| nanotube fiber filling | |

As shown, depending upon the coating formulation, a wide variety of coating characteristics was obtained. Mineral filled epoxy, such as the silica mineral filled epoxy (D) had a high initial charge followed by a more rapid decay as compared to the chromocene reactor wall coating (A). The PPS/PTFE (B) coating had lower initial charge decay as compared to the chromocene reactor wall coating (A), but a time decay closely resembling the chromocene reactor wall coating (A). PPS (C) had charge decay characteristics very similar to that of the silica filled epoxy (D). The graphite filled coating (E) had a high initial charge followed by a very rapid decay in the charge profile. The carbon nanontube filler (F) gave a very low initial charge and extremely fast rate of decay. These measurements provided the data to select a coating using the measured charge decay data to approximate the charge decay characteristics of the chromocene reactor wall coating.

### Testing of Selected Coating

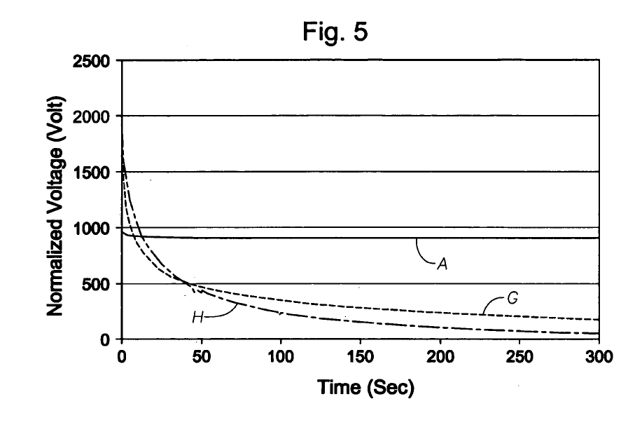

Based on the test data discussed above, a silica filled epoxy-based commercial coating was selected for testing in a polymerization reactor. A pilot scale reactor was coated with the silica filled epoxy formulation. The reactor had a diameter of 22.5 inches and bed height of 11.4 feet. The coating was uniformly applied to the reactor wall, distributor plate and bottom section below the distributor plate. It was cured at 185° F. Charge decay measurements and thickness measurements were obtained. A coating of 6-8 mils was obtained and shown to be much less variable than that of the chromocene reactor wall coating (A). Results of the charge decay measurements after the coating was applied and before the reactor was placed in operation are shown in FIG. 5 and labeled as curve “G.”

The reactor was then started up and a 31 day period of operation commenced using a metallocene catalyst to produce a wide variety of reactor resin grades. Following the 31 days of operation, charge decay measurements were again obtained using an applied corona voltage of 10,000 volts and are shown in FIG. 5 as curve “H.”

In both data sets G and H, the silica filled epoxy-based commercial coating applied to the pilot plant reactor had a much higher initial charge and more rapid rate of decay as compared to the chromocene reactor wall coating (A) showing the ability of the technique to distinguish the coating characteristics. Operating the reactor using the metallocene catalyst, as can be seen by curve H, resulted in approximately the same level of initial charge, but a slightly higher degree of decay than curve G. Without being bound to theory, it is believed that the cause for this decay can be attributed to either the effect of the metallocene catalyst or continued curing of the coating during the 31 day test period.

The pilot plant reactor operation was stable and free of sheeting, with reduced levels of charging on the plate as measured by static probes attached to the plate caps. This successful and stable operation demonstrated the ability of the method to select a suitable semi-conductive coating for use in a polymerization reactor.

While the present invention has been described and illustrated by reference to particular embodiments, those of ordinary skill in the art will appreciate that the invention lends itself to variations not necessarily illustrated herein. For example, it is contemplated that other methods of evaluating the electrical performance of a semi-conductive coating other than those discussed herein may be suitable to achieve the desired results. It is also contemplated that the process of the invention may be used to select semi-conductive coatings other than those mentioned herein. Therefore, the spirit and scope of the appended claims should not be limited to the description of the preferred versions contained herein.

The phrases, unless otherwise specified, “consists essentially of” and “consisting essentially of” do not exclude the presence of other steps, elements, or materials, whether or not, specifically mentioned in this specification, as along as such steps, elements, or materials, do not affect the basic and novel characteristics of the invention, additionally, they do not exclude impurities normally associated with the elements and materials used.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All priority documents are herein fully incorporated by reference for all jurisdictions in which such incorporation is permitted and to the extent such disclosure is consistent with the description of the present invention. Further, all documents and references cited herein, including testing procedures, publications, patents, journal articles, etc. are herein fully incorporated by reference for all jurisdictions in which such incorporation is permitted and to the extent such disclosure is consistent with the description of the present invention.

1. A method of selecting a semi-conductive coating for a polyolefin reaction system comprising the steps of:
a. determining a charge decay performance of a semi-conductive coating;
b. selecting a semi-conductive coating based on the charge decay performance; and
c. applying the selected semi-conductive coating to at least a portion of an inner surface of a polyolefin reaction system;
wherein the charge decay performance of the selected semi-conductive coating is characterized as having a rate of charge decay of greater than 50% in 300 seconds.

2. The method of claim 1, wherein the selecting comprises comparing a desired charge decay performance to the determined charge decay performance of the semi-conductive coating.

3. The method of claim 2, wherein the desired charge decay performance is compared to the determined charge decay performance of a plurality of semi-conductive coatings and the semi-conductive coating having the charge decay performance closest to the desired charge decay performance is selected.

4. The method of claim 1, wherein the determining comprises:
a. applying a corona voltage to the semi-conductive coating; and
b. measuring voltage retention over time of the semi-conductive coating.

5. The method of claim 4, wherein the corona voltage applied is between minus 10,000 and positive 10,000 volts.

6. The method of claim 1, wherein the charge decay performance of the selected semi-conductive coating is characterized as having a normalized residual charge of greater than 100 volts.

7. The method of claim 1, wherein the charge decay performance of the selected semi-conductive coating is characterized as having a normalized residual charge of 100 to 5,000 volts.

8. The method of claim 1, wherein the charge decay performance of the selected semi-conductive coating is characterized as having a rate of charge decay of greater than 90% in 300 seconds.

9. The method of claim 1, further comprising the step of confirming the charge decay performance of the semi-conductive coating by:
a. placing a tube internally coated with the semi-conductive coating in a Faraday cage;
b. charging a polymer to the tube;
c. fluidizing the polymer; and
d. measuring a net charge generation as a function of time.

10. A method of selecting a semi-conductive coating for a polyolefin reaction system comprising the steps of:
a. determining an electrical charge performance characteristic of at least one semi-conductive coating;
b. selecting a semi-conductive coating based on the electrical charge performance characteristic; and
c. applying the selected semi-conductive coating to at least a portion of an inner surface of a polyolefin reaction system;
wherein 1% to 50% of an applied electrical charge imposed is retained by the selected semi-conductive coating for at least 300 seconds.

11. The method of claim 10, wherein the retained portion of the applied electrical charge is 2% to 25% of the applied electrical charge.

12. The method of claim 10, wherein the electrical charge performance characteristic represents an ability of the semi-conductive coating to transfer an applied electrical charge imposed on a semi-conductive coating surface to a substrate.

13. The method of claim 10, wherein the selected semi-conductive coating transfers greater than 50% of the applied electrical charge to the substrate within about 300 seconds.

14. A fluidized bed reactor vessel wherein at least a portion of a reactor internal surface is coated with a semi-conductive coating, wherein the semi-conductive coating comprises polyphenylene sulfide, a polyphenylene sulfide and polytetrafluoroethylene mixture, mineral fillers, a graphite in a polymeric base, or carbon nanotube fibers in a polymeric base, and wherein the semi-conductive coating is characterized as having either:
i) a rate of charge decay of greater than 50% in 300 seconds, or
ii) a normalized residual charge with an absolute value of 100 to 5,000 volts 300 seconds after applying a corona voltage with an absolute value of 8,000 to 12,000 volts.

15. The device of claim 14, wherein the mineral fillers comprise elements or oxides of silicon, aluminum, boron, or magnesium.

16. The device of claim 14, wherein the semi-conductive coating is a solvent-based coating or an epoxy-based coating.

17. The method of claim 1, wherein the polyolefin reaction system is a polyethylene reaction system.
